(19) United States
(12) Patent Application Publication
(10) Pub. No.: US 2017/0025642 A1
(43) Pub. Date: Jan. 26, 2017

(54) DISPLAY

(71) Applicant: EVERDISPLAY OPTRONICS (SHANGHAI) LIMITED, Shanghai City (CN)

(72) Inventor: Yanhu LI, SHANGHAI CITY (CN)

(73) Assignee: EVERDISPLAY OPTRONICS (SHANGHAI) LIMITED, SHANGHAI CITY (CN)

(21) Appl. No.: 15/149,375

(22) Filed: May 9, 2016

(30) Foreign Application Priority Data
Jul. 24, 2015 (CN) 201510439853.X

(51) Int. Cl. H01L 51/52; H01L 27/32; G02F 1/1335; H01L 51/56

(52) U.S. Cl. CPC H01L 51/5271; H01L 51/56; H01L 51/5253; H01L 27/3244; G02F 1/133553

(57) ABSTRACT

The present disclosure provides a display, including a substrate, a display unit and a package structure, wherein the display unit is disposed between the substrate and the package structure, and the substrate or the package structure is a single-sided visible structure. Since the substrate or the package structure in the display is configured as the single-sided visible structure, the incident intensity of backside light is reduced, while light transmittance of the display unit is not affected, such that the backside light can be reduced from entering viewer's visual field, so as to increase the contrast of the display.

### CROSS-REFERENCE TO RELATED APPLICATIONS

The present application is based upon and claims priority to Chinese Patent Application No. 201510439853.X, filed Jul. 24, 2015, the entire contents of which are incorporated herein by reference.

### TECHNICAL FIELD

The present disclosure relates to a display, and more particularly, to a display capable of improving the display contrast.

### BACKGROUND

A transparent display generally refers to a display which is capable of forming a transparent display state such that a viewer can see both the image displayed on the display and the scene on backside of the display. The transparent display's market grows rapidly, and the transparent display may be applied in various of aspects such as: personal applications (watches, mobile phones, tablet computers, notebook computers, etc.); household appliances' displaying (refrigerators, microwave ovens, etc.), TV sets or large-screen displays; advertising display screens, office displaying, education, buildings (windows); military purposes; head-up displays (vehicles, aircrafts), and the like.

The transparent display can be classified into head-up display, transparent liquid crystal display (transparent LCD) and transparent organic electroluminescent display (transparent OLED). Among these kinds of transparent displaying, the head-up displaying is achieved by image projection, while the transparent LCD and the transparent OLED belong to transparent displaying in the true sense. However, the transparent display has a drawback of low contrast. The contrast of the transparent display is much lower than that of an ordinary display for the reasons below.

Take the transparent OLED as an example, as shown in FIGS. 1 and 2, a light emitting region of the transparent OLED generally include GRB pixel regions which display green, red and blue colors, and a non-light emitting region T of the transparent OLED is a region other than the light emitting region. The non-light emitting region T is generally a transparent transmission region. During the display's displaying, as shown in FIG. 2, when a viewer views from direction a, backside light will also enter the viewer's visual field from direction b, and this portion of light will affect the contrast of the display, thus affecting the displaying effect.

### SUMMARY

An object of the present disclosure is to increase the contrast of the transparent display by modifying the transparent display.

To achieve the above object, the present disclosure provides a display, including a substrate, a display unit and a package structure, wherein the display unit is disposed between the substrate and the package structure, and the substrate or the package structure is a single-sided visible structure.

Optionally, a reflection film is disposed on at least one surface of the substrate.

Optionally, the package structure is a cover plate or a package film, the cover plate is a single-sided visible cover plate, and the package film is a single-sided visible package film.

Optionally, a reflection film is disposed on at least one surface of the cover plate or the package film.

Optionally, the reflection film is selected from a group consisting of a metal reflection film, a dielectric reflection film, or a metal-dielectric reflection film.

Optionally, the metal reflection film is formed of a material selected from a group consisting of silver, aluminum, magnesium, copper, gold, chromium, platinum, tungsten, molybdenum, titanium, palladium, or an alloy formed by one or more of the foregoing metals.

Optionally, a dielectric layer of the dielectric reflection film is formed of a material selected from a group consisting of silicon oxide, titanium oxide, zinc oxide, niobium oxide, tantalum oxide, aluminum oxide, indium oxide, magnesium oxide, tin oxide, silicon nitride, titanium nitride, zinc nitride, niobium nitride, tantalum nitride, aluminum nitride, indium nitride, magnesium nitride, tin nitride, or a combination of any of the foregoing.

Optionally, the reflection film has a thickness in the range of 0-200 Å.

Optionally, the reflection film is manufactured by evaporation plating, sputtering, chemical vapor deposition, spin coating, spray coating, screen printing or ink jet printing.

Optionally, when the reflection film is the metal reflection film or the metal-dielectric reflection film, the display further includes a protection layer which covers the reflection film.

Optionally, the protection layer is formed of a material selected from a group consisting of an oxide, a nitride, a nitrogen oxide, a fluoride, or a combination thereof.

Optionally, the protection layer is formed of a material selected from a group consisting of aluminum oxide, zirconium oxide, zinc oxide, titanium oxide, magnesium oxide, silicon oxide, silicon nitride, aluminum nitride, titanium nitride, silicon oxynitride, aluminum oxynitride, titanium oxynitride, magnesium fluoride, sodium fluoride, or a combination of any of the foregoing.

Optionally, the display is a transparent liquid crystal display or a transparent organic electroluminescent display.

Compared with the prior art, the display of the present disclosure has at least the following advantageous effects. Since the substrate or the package structure in the display is configured as the single-sided visible structure, the incident intensity of backside light is reduced, while light transmittance of the display unit is not affected, such that the backside light can be reduced from entering viewer's visual field, so as to increase the contrast of the display.

### BRIEF DESCRIPTION OF THE DRAWINGS

FIG. 1 is a diagram of light emitting of a transparent OLED in the prior art;

FIG. 2 is a structural diagram of a transparent display in the prior art; and

FIGS. 3 to 6 are structural diagrams of transparent displays according to various embodiments of the present disclosure.

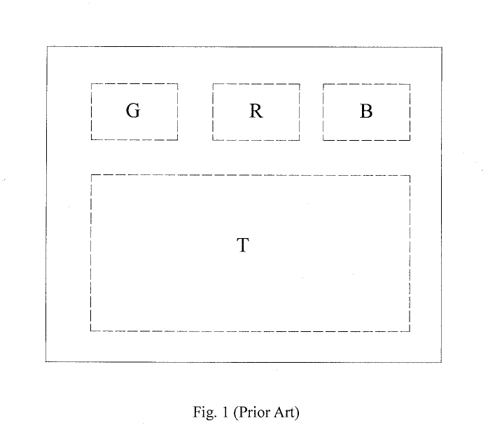

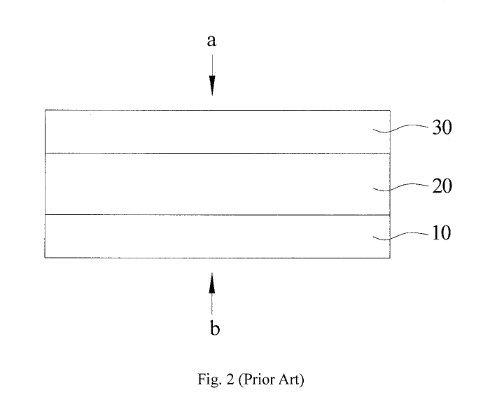

The reference numerals are listed as follows:

| | |
|---|---|
| 10: substrate | 20: display unit |
| 30: package structure | 301: cover plate |
| 302: package film | 40: reflection film |
| 50: protection layer | a, b: direction |
| GRB: OLED light-emitting region | T: OLED non-light emitting region |

### DESCRIPTION OF THE EMBODIMENTS

The exemplary embodiments will now be described more fully with reference to the accompanying drawings. However, the exemplary embodiments can be implemented in various forms and should not be understood as being limited to the embodiments set forth herein; rather, these embodiments are provided so that this disclosure will be thorough and complete, and the conception of exemplary embodiments will be fully conveyed to those skilled in the art. In the drawings, the same reference numerals denote the same or similar structures, thus any repetitive description thereof will be omitted.

In the present disclosure, the description of direction or position, such as up/down, between, etc., is described based on the example shown in the drawings, but may also be changed as needed, and all the changes will be encompassed within the scope of the present disclosure. In the present disclosure, upper surface, lower surface, front surface and back surface are all defined with reference to a viewer, that is, the surfaces facing the viewer are upper surface and front surface, while the surfaces in opposite direction are lower surface and back surface.

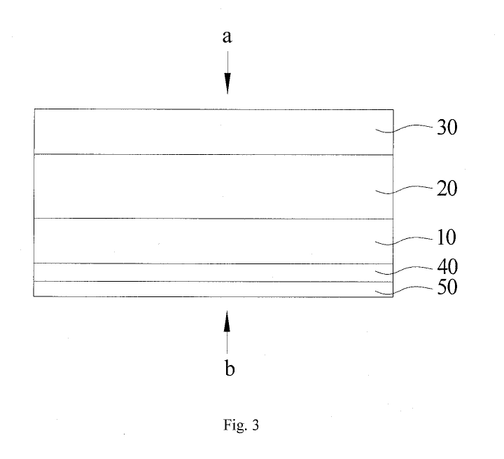

Referring to FIGS. 3 to 6, according to one embodiment of the present disclosure, the transparent display includes a substrate 10, a display unit 20 and a package structure 30, and the display unit 20 is disposed between the substrate 10 and the package structure 30. The package structure 30 covers a light emitting region and a non-light emitting region of the display unit 20. The substrate 10 or the package structure 30 is a single-sided visible structure. The package structure 30 may be a cover plate 301 or a package film 302 used for packaging.

In order to increase the display contrast, in one embodiment, the substrate 10 is configured as a single-sided visible substrate, or the cover plate 301 is configured as a single-sided visible cover plate, or the package film 302 is configured as a single-sided visible package film. Preferably, the substrate 10 is configured as a single-sided visible substrate. Thus, the transparent display may be formed to have a structure as follows: single-sided visible substrate/display unit/package structure, substrate/display unit/single-sided visible cover plate, or substrate/display unit/single-sided visible package film. In the present disclosure, the meaning of “single-sided visible” is: the substrate, the cover plate or the package film configured as single-sided visible has a certain reflection on backside light whose brightness is relatively strong, so as to reduce the brightness thereof.

The single-sided visible substrate, the single-sided visible cover plate and the single-sided visible package film can be achieved by the same method. The single-sided visible substrate is described hereinafter as an example, but the technical features thereof may apply to the single-sided visible cover plate and the single-sided visible package film as well.

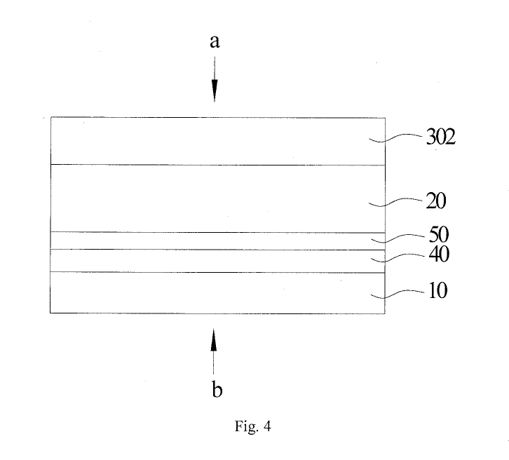

The single-sided visible substrate is achieved by disposing a reflection film 40 on at least one surface of the substrate 10, and preferably on a lower surface of the substrate 10. That is, the reflection film 40 is disposed on the lower surface of the substrate 10, as shown in FIG. 3. Alternatively, the reflection film 40 may be disposed on an upper surface of the substrate 10, as shown in FIG. 4. The reflection film 40 may be selected from a metal reflection film, a dielectric reflection film, or a metal-dielectric reflection film.

The metal reflection film may be formed of a material selected from a group consisting of silver, aluminum, magnesium, copper, gold, chromium, platinum, tungsten, molybdenum, titanium, palladium, or an alloy formed by one or more of the foregoing metals. Elemental metal is preferably silver or aluminum, and the alloy is preferably silver-aluminum alloy.

The dielectric reflection film includes a plurality of dielectric layers. Adjacent dielectric layers are formed of different materials, and may have the same thickness or different thicknesses. The dielectric reflection film may be constructed by alternately laminating at least two dielectric layers having different refractive indices. For example, the dielectric reflection film may be constructed by alternately laminating a titanium oxide layer and a silicon oxide layer for about 5 to 10 layers. A dielectric layer may be formed of a material selected from a group consisting of silicon oxide, titanium oxide, zinc oxide, niobium oxide, tantalum oxide, aluminum oxide, indium oxide, magnesium oxide, tin oxide, silicon nitride, titanium nitride, zinc nitride, niobium nitride, tantalum nitride, aluminum nitride, indium nitride, magnesium nitride, tin nitride, or a combination of any of the foregoing compounds. By adjusting the thickness of the dielectric reflection film such that a portion of incident light is reflected, the dielectric reflection film may be used as a semi-transmissive and semi-reflective film that can transmit a portion of incident light.

The metal-dielectric reflection film is formed by a combination of a metal reflection film and a dielectric layer, which may be obtained by further depositing the dielectric layer on the metal reflection film.

A thickness of the reflection film 40 may be in the range of 0-200 Å, and preferably is 100 Å. The reflection film 40 with such a thickness substantially does not affect light transmission through the display unit 20, so will not cause much affection on transparency effect of the transparent display. It should be noted that when the brightness of backside light is relatively high, the thickness of the reflection film 40 may be increased, or the reflection film 40 may be simultaneously disposed on both sides of the substrate 10.

The process for manufacturing the reflection film 40 may include but not limited to: evaporation plating, sputtering, chemical vapor deposition, spin coating, spray coating, screen printing or ink jet printing.

The single-sided visible substrate can be achieved based on the following principle. Generally, light has reversibility, that is, if a light can be irradiated from a point p1 to a point p2, then the light can also be irradiated from the point p2 to the point p1. When a very thin reflection film 40 is disposed on the substrate 10, such a substrate cannot reflect all of the incident light, but can transmit part of the incident light. With reference to the principle of unidirectional glass, only depending on the intensity of light, the unidirectional glass is merely visible from one side. Invisible side (i.e., light reflecting side) of the unidirectional glass has a higher light intensity, while visible side (i.e., light transmitting side) of the unidirectional glass has a lower light intensity. High intensity of lights from the invisible side are mostly reflected, but low intensity of lights from the visible side cannot be seen clearly due to reflection, or even cannot be seen at all. Thus, when viewing from the side with higher light intensity, the unidirectional glass seems like an ordinary mirror, images at the side with lower light intensity substantially will not be irradiated into the side with higher light intensity due to reflection; on the contrary, when viewing from the side with lower light intensity, images at the side with higher light intensity can be seen clearly because high intensity of lights transmit through the thin reflection film from the side with higher light intensity, while the weak reflected light from the side with lower light intensity can be ignored substantially.

In the present disclosure, the single-sided visible substrate is achieved by using and modifying the principle of the unidirectional glass, so as to increase the display contrast. Specifically, the reflection film 40 is for example a silver film; as shown in FIG. 3, in case a viewer stands at the front side of the display, when the viewer views from direction a, backside light with higher intensity from direction b is reflected by the silver film, so the intensity thereof will be reduced after the backside light transmits through the substrate 10 and the silver film. Lights emitted from the display unit 20 normally enter the viewer's visual field, whereas the intensity of backside lights incident from direction b reduces, thereby the contrast of the display is increased when viewing from direction a, improving the displaying effect of the transparent display. As shown in FIG. 4, when the reflection film 40 is disposed on an upper surface of the substrate 10, the procedure for reducing the backside light intensity by the reflection film 40 is similar to that of FIG. 3.

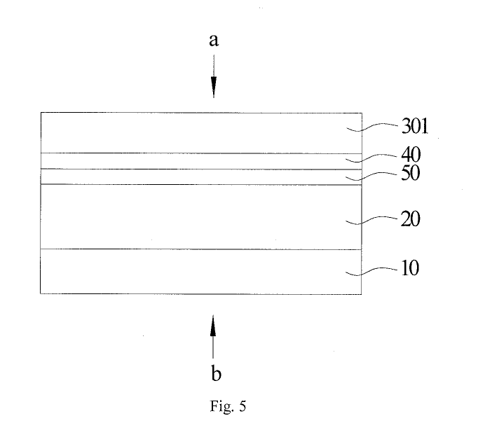

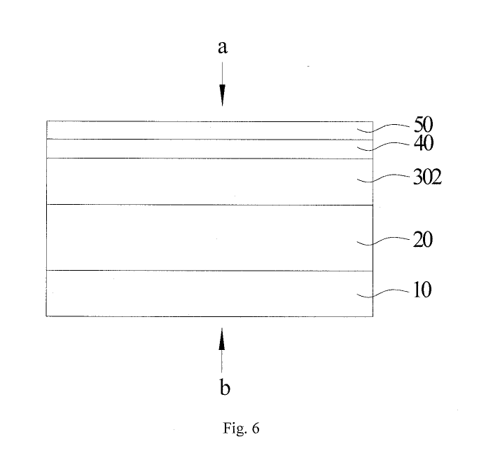

As shown in FIG. 5, when the cover plate 301 is configured as a single-sided visible cover plate, or as shown in FIG. 6, when the package film 302 is configured as a single-sided visible package film, the backside light with higher intensity can also be reduced from entering viewer's visual field, so as to increase the contrast of the transparent display.

In the present disclosure, the substrate 10 and the cover plate 301 may be a rigid substrate or a flexible substrate, including but not limited to a glass substrate, a quartz substrate, a metal substrate, an organic polymer substrate or a metal oxide substrate, and preferably be a glass substrate, a quartz substrate or an organic polymer substrate with good transparency.

In the present disclosure, the package film 302 may include but not limited to an inorganic film, an organic film, and a film constructed by alternately laminating an inorganic film and an organic film. The inorganic film may be formed of a material selected from a group consisting of aluminum oxide, zirconium oxide, zinc oxide, titanium oxide, magnesium oxide, silicon oxide, silicon nitride, aluminum nitride, titanium nitride, silicon oxynitride, aluminum oxynitride, titanium oxynitride, magnesium fluoride, sodium fluoride, and combinations thereof; the organic film may be formed of a material selected from a group consisting of polyamide, polyimide, polycarbonate, polypropylene, polyacrylic acid, polyacrylates, polyurethane acrylates, polyester, polyethylene, polystyrene, polysiloxane, polysilazane, epoxy resins, acrylate, amine acrylate, or combinations thereof; the present invention does not limit the material, combination and laminated structure of the package film 302.

When the reflection film 40 is the metal reflection film or the metal-dielectric reflection film, as shown in FIGS. 3 to 6, in order to avoid metals or alloys from being exposed to outer environments and deteriorating, a protection layer 50 is further provided in the transparent display to cover the reflection film 40. Specifically, as shown in FIG. 3, when the reflection film 40 is positioned below the substrate 10, the protection layer 50 is positioned below the substrate 10 and covers the reflection film 40; as shown in FIG. 4, when the reflection film 40 is positioned above the substrate 10, the protection layer 50 is positioned above the substrate 10 and covers the reflection film 40; as shown in FIG. 5, when the reflection film 40 is positioned below the cover plate 301 (or the package film 302), the protection layer 50 is positioned below the cover plate 301 and covers the reflection film 40; as shown in FIG. 6, when the reflection film 40 is positioned above the package film 302 (or the cover plate 301), the protection layer 50 is positioned above the package film 302 and covers the reflection film 40.

The protection layer 50 has a high light transmittance, and a high waterproof and oxygen-proof performance, while the protection layer 50 also has a function of preventing the metal reflection film from metal-diffusion. A material of the protection layer 50 may include, but not limited to, one of the following materials and combinations thereof: an oxide, a nitride, an oxynitride. The oxide includes but not limited to aluminum oxide, zirconium oxide, zinc oxide, titanium oxide, magnesium oxide and silicon oxide. The nitride includes but not limited to silicon nitride, aluminum nitride and titanium nitride. The oxynitride includes but not limited to silicon oxynitride, aluminum oxynitride and titanium oxynitride.

A thickness of the protection layer 50 may be in the range of 0-1000 Å.

The process for manufacturing the protection layer 50 may include but not limited to: evaporation plating, sputtering, chemical vapor deposition, spin coating, spray coating, screen printing or ink jet printing.

In one example, when the light intensity of the display unit is 1000 nit, and the intensity of the backside light is 200 nit, the transparent display of the prior art has a contrast (i.e., a contrast between brightness and darkness) of 6. If the transparent display of the present invention is applied, the reflection film 40 of the single-sided visible substrate is a silver film having a thickness of 80 Å, and the reflection film 40 is disposed below the substrate 10, then the single-sided visible substrate may reduce the intensity of the backside light down to 20 nit, the contrast of the transparent display is 51, that is, the contrast is increased to as high as nearly 9 times. Accordingly, the contrast of the transparent display can be increased significantly by adopting the single-sided visible substrate, the single-sided visible cover plate or the single-sided visible package film of the present disclosure.

The single-sided visible substrate, the single-sided visible cover plate and the single-sided visible package film of the present disclosure may be applied in a transparent LCD or a transparent OLED.

In particular, the transparent LCD generally includes a thin film transistor array substrate, a color filter substrate, and a liquid crystal layer filled between the thin film transistor array substrate and the color filter substrate. The color filter substrate is provided with a plurality of transparent pixel units, and the thin film transistor array substrate has transparent regions corresponding to the transparent pixel units, so as to achieve a transparent effect.

In order to increase the contrast of the transparent LCD, the reflection film 40 as described above may be disposed on the thin film transistor array substrate or the color filter substrate. The reflection film 40 may be disposed on one side of the thin film transistor array substrate, or may be disposed on both sides thereof; the reflection film 40 may be disposed on one side or both sides of the color filter substrate; and a protection layer 50 may be further provided. By means of reflecting the backside light by the reflection film 40, the incident intensity of the backside light is reduced, thereby increasing the contrast of the transparent LCD.

The transparent OLED generally includes a thin film transistor array substrate, a package structure 30 (e.g., a cover plate 301 or a package film 302, etc.), and organic light emitting diodes located between the thin film transistor array substrate and the package structure 30. The organic light emitting diode includes an anode, a cathode, and an organic functional layer located between the anode and the cathode. The organic functional layer may at least include an organic light emitting layer, and may further include one or more of a hole injection layer, a hole transport layer, an electron barrier layer, a hole barrier layer, an electron transport layer, and an electron injection layer. The transparent OLED may achieve a transparent display effect by adopting transparent electrodes, the organic functional layer and the package structure.

In order to increase the contrast of the transparent OLED, the reflection film 40 as described above may be disposed on the substrate 10, the cover plate 301 or the package film 302. The reflection film 40 may be disposed on one side of the thin film transistor array substrate, or may be disposed on both sides thereof; the reflection film 40 may be disposed on one side or both sides of the cover plate 301 (or the package film 302) in the package structure; and a protection layer 50 may be further provided. By means of reflecting the backside light by the reflection film 40, the incident intensity of the backside light is reduced, thereby increasing the contrast of the transparent OLED.

Example embodiments of the present disclosure are particularly illustrated and described as above. However, those skilled in the art will appreciate that, various modifications and substitutions may be made to embodiments of the disclosure without departing from the spirit and scope of the present invention. All of such modifications and substitutions will fall within the scope as defined by the claims of the present disclosure.

What is claimed is:

1. A display, comprising: a substrate, a display unit and a package structure,
wherein the display unit is disposed between the substrate and the package structure, and the substrate or the package structure is a single-sided visible structure.

2. The display according to claim 1, wherein a reflection film is disposed on at least one surface of the substrate.

3. The display according to claim 1, wherein the package structure is a cover plate or a package film, the cover plate is a single-sided visible cover plate, and the package film is a single-sided visible package film.

4. The display according to claim 3, wherein a reflection film is disposed on at least one surface of the cover plate or the package film.

5. The display according to claim 2, wherein the reflection film is selected from a metal reflection film, a dielectric reflection film, or a metal-dielectric reflection film.

6. The display according to claim 4, wherein the reflection film is selected from a metal reflection film, a dielectric reflection film, or a metal-dielectric reflection film.

7. The display according to claim 5, wherein the metal reflection film is formed of a material selected from a group consisting of silver, aluminum, magnesium, copper, gold, chromium, platinum, tungsten, molybdenum, titanium, palladium, or an alloy formed by one or more of the foregoing metals.

8. The display according to claim 5, wherein a dielectric layer of the dielectric reflection film is formed of a material selected from a group consisting of silicon oxide, titanium oxide, zinc oxide, niobium oxide, tantalum oxide, aluminum oxide, indium oxide, magnesium oxide, tin oxide, silicon nitride, titanium nitride, zinc nitride, niobium nitride, tantalum nitride, aluminum nitride, indium nitride, magnesium nitride, tin nitride, or a combination of any of the foregoing.

9. The display according to claim 6, wherein the metal reflection film is formed of a material selected from a group consisting of silver, aluminum, magnesium, copper, gold, chromium, platinum, tungsten, molybdenum, titanium, palladium, or an alloy formed by one or more of the foregoing metals.

10. The display according to claim 6, wherein a dielectric layer of the dielectric reflection film is formed of a material selected from a group consisting of silicon oxide, titanium oxide, zinc oxide, niobium oxide, tantalum oxide, aluminum oxide, indium oxide, magnesium oxide, tin oxide, silicon nitride, titanium nitride, zinc nitride, niobium nitride, tantalum nitride, aluminum nitride, indium nitride, magnesium nitride, tin nitride, or a combination of any of the foregoing.

11. The display according to claim 2, wherein the reflection film has a thickness in the range of 0-200 Å.

12. The display according to claim 4, wherein the reflection film has a thickness in the range of 0-200 Å.

13. The display according to claim 2, wherein the reflection film is manufactured by evaporation plating, sputtering, chemical vapor deposition, spin coating, spray coating, screen printing or ink jet printing.

14. The display according to claim 4, wherein the reflection film is manufactured by evaporation plating, sputtering, chemical vapor deposition, spin coating, spray coating, screen printing or ink jet printing.

15. The display according to claim 5, wherein when the reflection film is the metal reflection film or the metal-dielectric reflection film, the display further comprises a protection layer which covers the reflection film.

16. The display according to claim 6, wherein when the reflection film is the metal reflection film or the metal-dielectric reflection film, the display further comprises a protection layer which covers the reflection film.

17. The display according to claim 15, wherein the protection layer is formed of a material selected from a group consisting of an oxide, a nitride, a nitrogen oxide, a fluoride, or a combination thereof.

18. The display according to claim 15, wherein the protection layer is formed of a material selected from a group consisting of aluminum oxide, zirconium oxide, zinc oxide, titanium oxide, magnesium oxide, silicon oxide, silicon nitride, aluminum nitride, titanium nitride, silicon oxynitride, aluminum oxynitride, titanium oxynitride, magnesium fluoride, sodium fluoride, or a combination of any of the foregoing.

19. The display according to claim 16, wherein the protection layer is formed of a material selected from a group consisting of aluminum oxide, zirconium oxide, zinc oxide, titanium oxide, magnesium oxide, silicon oxide, silicon nitride, aluminum nitride, titanium nitride, silicon oxynitride, aluminum oxynitride, titanium oxynitride, magnesium fluoride, sodium fluoride, or a combination of any of the foregoing.

20. The display according to claim 1, wherein the display is a transparent liquid crystal display or a transparent organic electroluminescent display.
